(19) United States
(12) Patent Application Publication
(10) Pub. No.: US 2017/0229595 A1
(43) Pub. Date: Aug. 10, 2017

(54) APPARATUS FOR MAINTAINING CONCENTRATION AND ILLUMINATION SYSTEMS

(71) Applicant: Banyan Energy, Inc., Fremont, CA (US)

(72) Inventors: Gautam Ganguly, San Ramon, CA (US); David Kumar, San Jose, CA (US); Shewit Agaskar, San Rafael, CA (US); Jed Hsu, Fremont, CA (US)

(21) Appl. No.: 15/019,824

(22) Filed: Feb. 9, 2016

(51) Int. Cl. H01L 31/054; H01L 31/055; H02S 30/10

(52) U.S. Cl. CPC H01L 31/0543; H02S 30/10; H01L 31/055

(57) ABSTRACT

A system for collecting light energy through smaller photovoltaic cells (PV cell) such that the length of the PV cell is much greater than the width. The PV cells may be linear strung together and placed within a recess of a frame or pan that is part of a PV module. The PV module includes a lens and waveguide which provide advantages for focusing and concentrating the light energy by positioning a waveguide over the smaller PV cell and engaging the PV cell with a lens such that the lens is held by the frame.

### CROSS-REFERENCE TO RELATED APPLICATIONS

This application incorporates the following patents or applications, in their entirety, by reference: U.S. Pat. No. 8,705,914 titled REDIRECTING OPTICS FOR CONCENTRATION AND ILLUMINATION SYSTEMS and U.S. Pat. No. 8,561,878 titled LINEAR CELL STRINGING.

### TECHNICAL FIELD

This disclosure relates generally to methods and systems for light collection and delivery. These systems relate more specifically to the use of optics to concentrate sunlight into photovoltaic receivers and the apparatus used for this light collection.

### RELATED ART

Photovoltaic (PV) cells or solar cells are electronic devices that convert solar energy, or light energy into electricity. PV cells are, roughly, manufactured from circular silicon wafers and are often cut into a rectangular shape with the corners cut off. The PV cells are then placed within a PV module side by side. A standard PV module may include cells placed in a frame in a format of 6 cells by 10 cells (6×10), or 6 cells by 12 cells (6×12) or other formats.

The PV cells in a PV module are wired or soldered together in a series to create a higher additive voltage. The PV modules are necessarily waterproof or water-resistant so as not to short the electronics and electrical connections. Often a sheet of glass covers a sun-facing side of the module. Each PV module includes its own power box that captures the electricity produced from the PV cells.

PV cells tend to have a standard length and width of, roughly, 156 mm×156 mm. These are then placed together in a PV module as set forth above. PV cells may be cut into many different sizes and or shapes but the industry standard tends to be the 156 mm×156 mm.

Mirrors and other reflectors have been used in the solar energy art o help harness more of the solar energy into PV cells. Often times the reflectors do riot capture 100% of the solar energy because some energy is lost in the reflection.

Edge collectors or optical waveguides are used for collection and concentration of light; in particular, sunlight. An edge collector or optical waveguide is defined for this application as an optical device that receives light from a top surface, and delivers the concentrated energy to the edge of the device. In practice, optical waveguides are generally of the type described in U.S. Pat. Nos. 7,664,350 and 7,672,549. Other types of optical waveguides include luminescent solar concentrators, or dye luminescent solar concentrators.

### SUMMARY

This disclosure, at least in one aspect, relates to the use of frames for holding PV cells, optical waveguides, and a lens or lenses to aid in concentrating solar energy onto those PV cells and the method of assembly. The frame may include a recessed track or grooves or voids to hold and capture PV cells that have been cut and soldered together linearly in a manner the same or similar to that described in U.S. Pat. No. 8,561,878. The PV cells are cut into strips, instead of the standard 156 mm×156 mm.

The PV cells in the present description may be cut from the wafer into six thinner PV cells which may be 15 mm×125 mm. The PV cells may lay flat within the grooves. The PV cells may be secured by some type of adhesion or not. The track may be of a standard width to fit the linear PV cells so that the PV cells cannot shift laterally after being placed within the groove. The linear PV cells may lay within a frame which may comprise six tracks that the linear PV cells fit in. The linear PV cells may then be strung together 10 PV cells in length. The outlay of the PV cells may then be 6×10 PV cells; however, although the PV cells are thinner (15 mm×125 mm) they are able to capture as much solar energy and produce as much electricity as a standard cell of 156 mm×156 mm because of the optical waveguide and lens.

The optical waveguide may be positioned just above, or superior, the PV cells. The assembly of the PV module may include a gel or other optically transparent material that engages the PV cell and the waveguide to allow transfer of solar energy with little to no reflective loss of the solar energy. A lens is positioned superior, or on top of, the waveguide to concentrate the light or solar energy into the waveguide. The waveguide then uses total internal reflection to transfer the solar energy or light on the PV cell or the receiver.

At either end of the frame brackets may be place to “cap” the ends of the PV module. A waterproof or water resistant material is provided around the circumference of the frame to prevent water ingress into the assembly or system. At least one end bracket may include a vent to allow moisture or condensation to escape the internal structure of the PV module, however, preventing the ingress of any such moisture. GORE-TEX® may be used to cover the vents to allow moisture to pass in a single direction as described herein.

This assembly does not require its own power box top capture the electricity from the cells. The assembly allows for direct electrical lines to feed into an electrical system or multiple PV module into a signal electric gathering receptacle, power box or battery.

Other aspects, as well as the features and advantages of various aspects, of the disclosed subject matter will become apparent to those of ordinary skill in the art from the ensuing description, the accompanying drawings, and the appended claims.

### BRIEF DESCRIPTION OF THE DRAWINGS

In the drawings:

FIG. 1 illustrates a perspective view of an assembly with a frame, without a waveguide or a lens;

FIG. 2 illustrates a closer perspective view, and partial cutout, of the assembly of FIG. 1;

FIG. 3 illustrates a cutout view of a recess and a single photovoltaic cell (PV cell) of the assembly of FIG. 1;

FIG. 4 illustrates a side view of the lens and waveguide of the assembly;

FIG. 5 illustrates a side view of the assembly of FIG. 1 if the frame was for a single PV cell or PV cell string and is for illustrative purposes only.

FIG. 6 illustrates an exploded perspective view the assembly with with the frame, waveguide and lens;

FIG. 7 illustrates a side view of at least one end cap or end bracket;

FIG. 8 illustrates a side view of the end bracket of FIG. 6 engaged with the frame;

FIG. 9 illustrates a perspective view of an alternate embodiment of the assembly of FIG. 1;

FIG. 10 illustrates a side view of the assembly of FIG. 9;

FIG. 11 illustrates a side view of an alternate embodiment end cap or end bracket;

FIG. 12 illustrates a top view of the alternate embodiment of FIG. 9 with the PV cells in place; and

FIG. 13 illustrates a side view of the end bracket of FIG. 11 and frame of FIG. 9.

### DETAILED DESCRIPTION

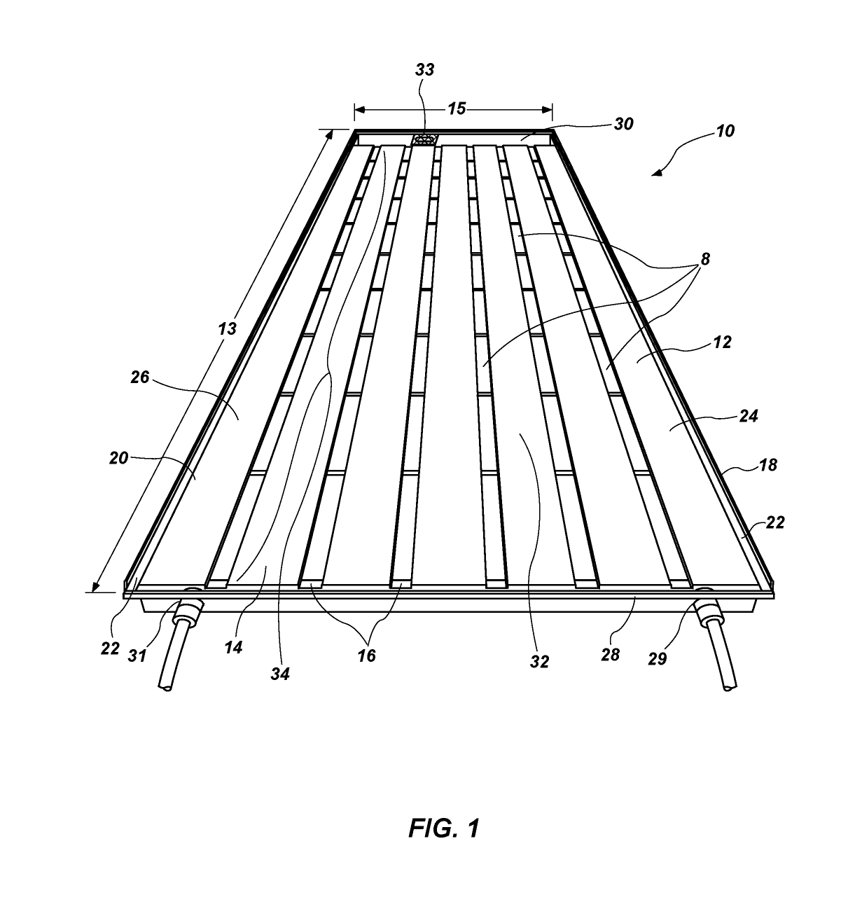

FIG. 1 illustrates an embodiment of a PV module assembly 10 with PV cells 8. The assembly 10 includes a body 12, or frame, which may have a longitudinal length 13 longer than its width 15. The body 12 may be a rectangular shape and may have sharp or rounded corners; however, other polygonal shapes are contemplated. The body 12 may comprise a top portion 14 that may include multiple grooves 16 or recesses extending the length 13 of the body 12. The body 12 may also include at least a first wall 18 and a second wall 20 extending along the longitudinal length 13 around the periphery of the body 12 wherein the first wall 18 and second wall 20 are opposite from each other on opposite sides of the body 12. The first wall 18 may extend superiorly from a first side 24 of the body 12 and the second wall 20 may extend superiorly from a second side 26 of the body 12. The first and second walls 18, 20 may include shoulders 22 that may extend laterally from the walls in a direction lateral to a center of the body 12. The shoulders may allow for a lens with a waveguide to be positioned on those shoulders 22.

The body may also include a third wall 28 extending along the width 15 from a third side of the body 12 and a fourth wall 30, opposite the third wall 28, extending long the width 15. The third and fourth walls 28,30 may also extend superiorly from the body 12 and may include shoulders 22 the same or similar to those extending laterally from the center of the body 12. The assembly 10 may comprise a cavity 32, or trough, between the walls 18, 20, 28, 30 creating a trough.

The third wall 28 may comprise at least one aperture, or a first aperture 29, to allow for a Multi-Contact (MC4) connectors, electrical connector or other transmission wire to pass therethrough. The first aperture 29 may include an insulator as well as a rubber cap or stopper, or other means known for securing a wire without allowing other materials to enter or exit. The rubber cap may maintain the wire within the aperture of the third wall 28 while also preventing ingress of water or moisture or other materials. The first aperture may be biased laterally toward one side of the third wall 28 close in proximity to the first wall 18. A second aperture 31 may be positioned laterally on the third wall 28 close in proximity to the second wall 20. The second aperture may comprise a rubber cap as well that performs in the same or substantially the same manner as the rubber cap of the first aperture 29.

The fourth wall 30 may include a third aperture 33 which may include a vent, or semi-permeable vent, to allow for moisture to escape from the cavity 32. The third aperture may be circular hole or an elliptical hole or any other circular or polygonal shape. The vent may semi-permeable and may be comprised of a breathable material that allows moisture to escape but prevents the penetration of moisture, much like GORE-TEX® or other possible polymer or venting material. The vent may be positioned along any portion of the fourth wall 30. It will be appreciated that multiple vents may be disbursed on any of the walls disclosed herein.

The recesses 16 may extend almost entirely from the third wall 28 to the fourth wall 30. The recesses 16 may be parallel to each other and the body 12 may include anywhere from four recesses to eight or more recesses. Some of the figures show an embodiment with six recesses. The recesses 16 may also run parallel to the first wall 18 and the second wall 20 in a longitudinal direction. Each recess 16 may extend the entire length of the body 12 or each recess may terminate prior the third wall 28 or the fourth wall 30. Each recess 16 may be configured to receive a solar cell string 34 as defined in U.S. Pat. No. 8,561,878 which is incorporated herein by reference. The solar cell strings 34 may slidably fit within the recesses 16. Each solar cell string 34 may be ten PV cells in length soldered together with electrical tabbing ribbon or by other electrical connection means. It will be appreciated that the length and width of the PV cells and PV cell strings 34 is dependent on the length of the body 12 of the assembly 10 and by the length and width of the recesses 16 of which the cell strings 34 lay. Standard PV modules incorporate a six cell by ten cell configuration and for ease in describing the present embodiment six cells by ten cells have also been utilized; however the cells described herein may be much narrower or thinner such as 15 mm×156 mm instead of 156 mm×156 mm.

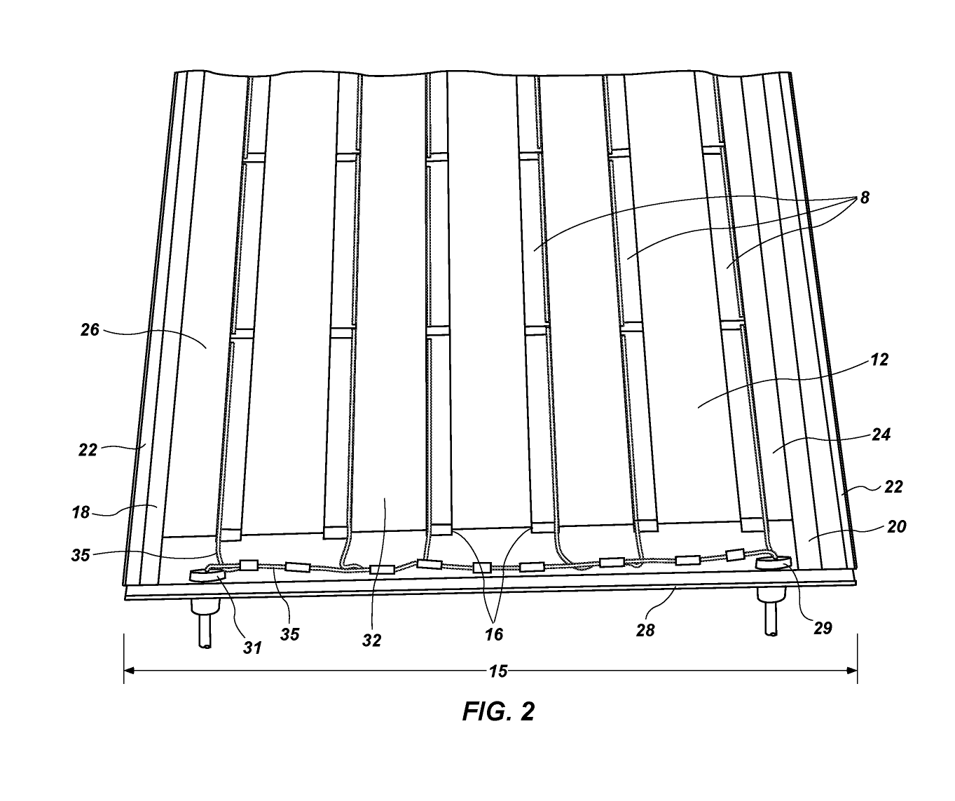

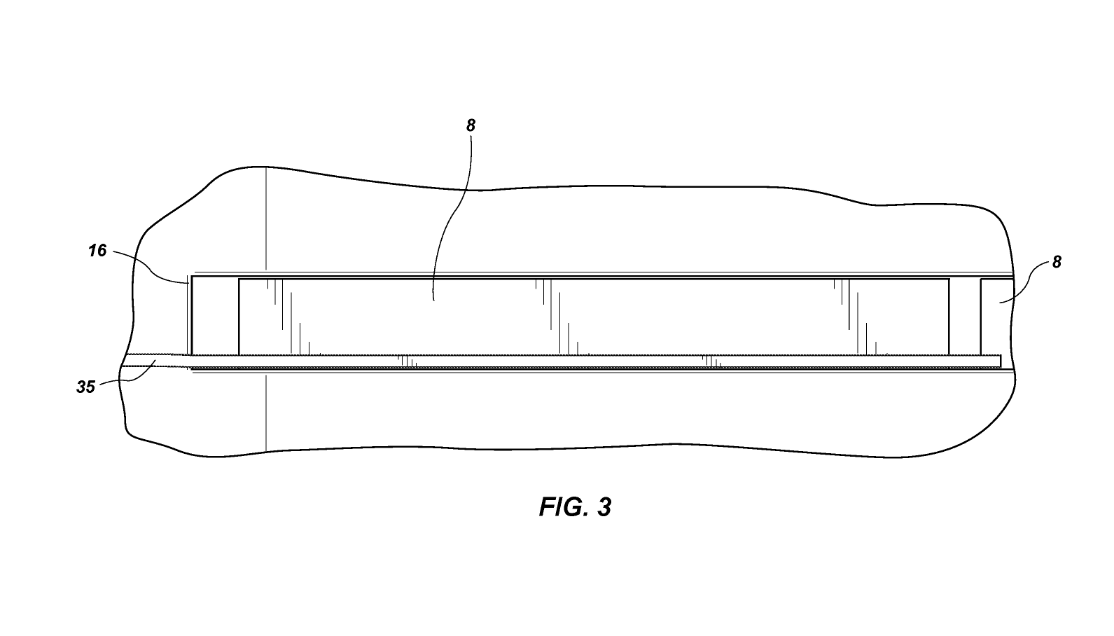

Referring to FIGS. 2 and 3, at the end of each cell string 34 electrical tabbing ribbon 35, or other means of electrical connection, may extend beyond the cell strings 34 and a separate tabbing ribbon which may run perpendicular to the tabbing ribbon(s) from the cell strings 34. The perpendicular running tabbing ribbons may be connected to the cell strings 34 tabbing ribbon(s), either through soldering or crimping or some other electrical contact means. This perpendicular tabbing ribbon is then connected to, wired to, soldered to or attached by other electrical means to the wires which pass through the rubber caps which pass through the apertures in the third wall 28. These electrical connections then allow the energy gathered by the PV cells of the cell string 34 to pass from the PV module to the energy harvester or battery.

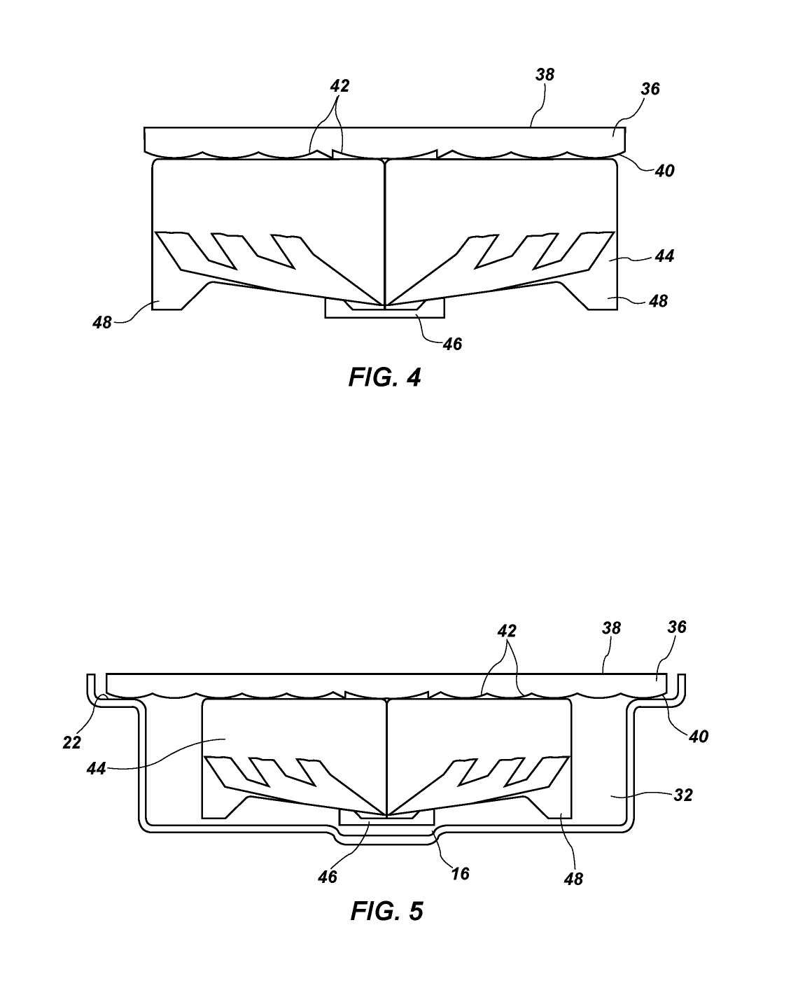

Referring to FIG. 4, a lens 36, or glass, is incorporated into the PV module 10 as the outer layer or top piece of the PV module 10. The lens 36 may be flat and smooth on a top portion 38 and ridged on the bottom portion 40. The ridges 42 are convex protrusions extending in a pattern on the bottom portion 40 wherein the pattern may consist of a large convex protrusion followed by a small convex protrusion followed by a five or six medium sized convex protrusions and then another small convex protrusion followed by a large protrusion. The medium sized protrusions are larger than the small protrusions but smaller than the large protrusions. It will be appreciated that the number of protrusions or ridges 42 and pattern may be altered and fewer medium ridges 42 may be used and a greater number of smaller or larger ridges 42 may also be used. This ridges 42, or convex protrusions, extend longitudinally the length of the lens 36 and run parallel to the recesses 16 of the body 12. The shape and configuration of the ridges 42 is for proper focus of light or light energy.

The lens may be made of glass, polymer, acrylic or other transparent material that provides the same means and methods of focusing the light to the waveguide.

A waveguide 44 is positioned against the lens 36 on the ridged bottom portion 40. The waveguide 44 may be secured in a number of different ways including, but not limited to, glue, silicone snap or press fit into grooves which may be carved into the lens 36. The waveguide and lens must be appropriately positioned with respect to one another with a tolerance of not great than plus or minus 0.1 mm. The waveguide 44 interacts with the lens in a manner as set forth in U.S. Pat. No. 8,705,914 which is incorporated herein by reference. The waveguide 44 is configured to sit within the cavity 32 and an edge 46 of the waveguide is positioned, or sits, just above the narrow PV cell. The waveguide 44 collects the light and concentrates the light at the edge 46 of the waveguide 44 for collection on a receiver, or the PV cell. The waveguide 44 may or may not touch the PV cell. In order for maximum light energy to be captured it is optimal that no air gap exist between the waveguide 44 and receiver, or PV cell. In the event the waveguide 44 is not in contact with the PV cell a non-refractive, index matching gel, or silicone, may be placed on top of the PV cell. The gel would engage both the PV cell and the waveguide 44 such that there is no air gap between the edge 46 of the waveguide 44 and the PV cell. The gel may be maintained within the recesses 16 such so that it does not spill onto the body 12 beyond the recesses 16.

The waveguide 44 may be made of materials such as acrylic, polymer, glass or other transparent material. However, the materials used may comprise those elements which allow refraction of light in the manner set forth in U.S. Pat. No. 8,705,914.

FIG. 5 depicts a single PV module assembly 10 for explanation purposes only and represents a single lens 36, waveguide 44, and frame 12. However, it will be appreciated that the PV module assembly described herein is intended to be a standard length width and size of a typical PV module. In this illustration it is readily recognizable the recess 16 at the base of the frame 12 that holds the PV cell. Likewise the walls which include the shoulder 22 that rests the lens 36 with the waveguide 44 secured to the lens 36.

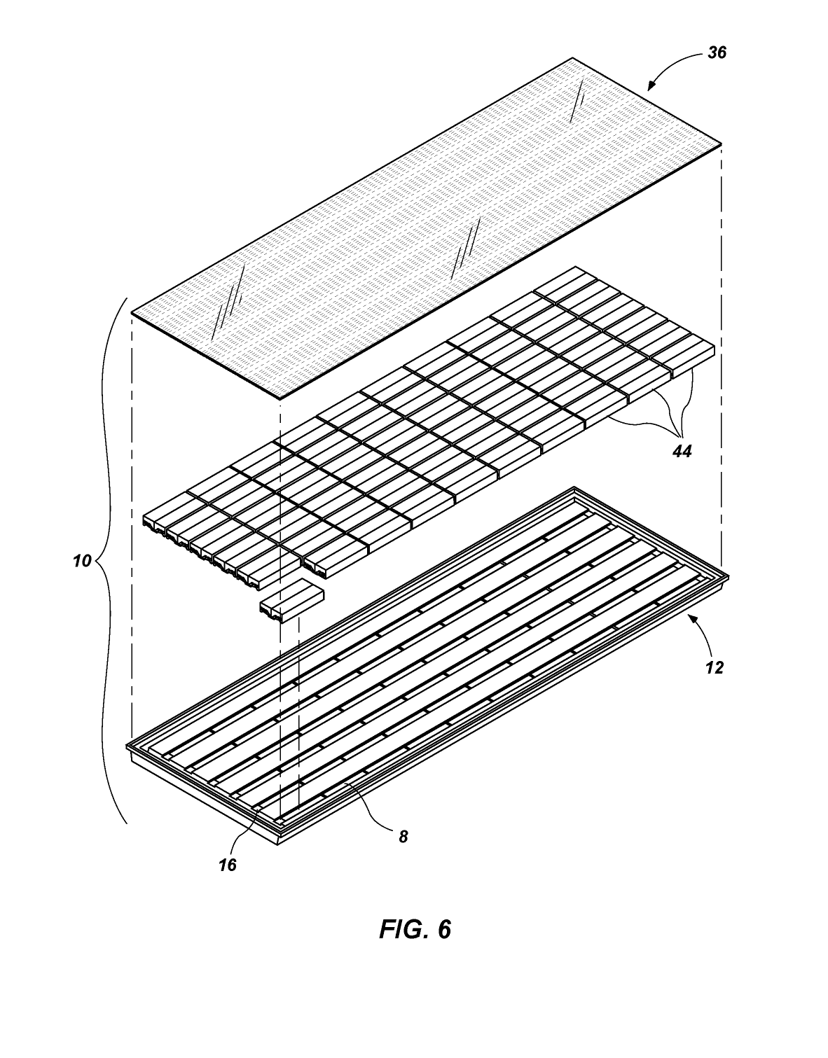

Referring to FIG. 6, each narrow PV cell (15 mm×156 mm, or similar) may include a waveguide 44 in order to concentrate enough light energy to reach the same efficiency of a standard PV cell (156 mm×156 mm). In a standard PV module comprising ten PV cells by six PV cells each cell may include a waveguide thus requiring sixty (60) waveguides for the PV module assembly 10. Multiple waveguides 44 may be secured to a single lens 36 wherein the lens length and width are sufficient to reside on the shoulders 22 of the walls 18, 20, 28, 30. The length of the waveguide 44 may be substantially similar to the length of the PV cell thus maximizing the light energy over the length of the PV cell. Each waveguide 44 may laterally touch an adjacent waveguide 44; however because of the length of a PV cell a waveguide 44 may not touch or be in direct contact with another waveguide on its proximal and distal ends. It will be appreciated that a single extruded waveguide may be utilized, or single piece, or single waveguide 44, may be machined that may sit within the frame 12 and engage the lens 36 and the PV cells; wherein the machined single piece, or extruded waveguide, may have the same or similar refractive properties as each individual waveguide 44. Similarly, a waveguide may be machined that runs the length 13 of the frame 12; wherein the single waveguide engages ten PV cells. Many other variations and dimensions of waveguides are contemplated herein and are within the scope of this disclosure.

The waveguide 44 may further include legs 48 extending away from a body of the waveguide 44. The legs 48 may extend from the proximal and distal ends of the waveguide 44. The legs 48 may straddle the recess 16 when positioned within the cavity 32 and provide additional support to the waveguide 44 and support to the lens 36 which sits superior to the waveguide 44 when the PV module assembly 10 is assembled.

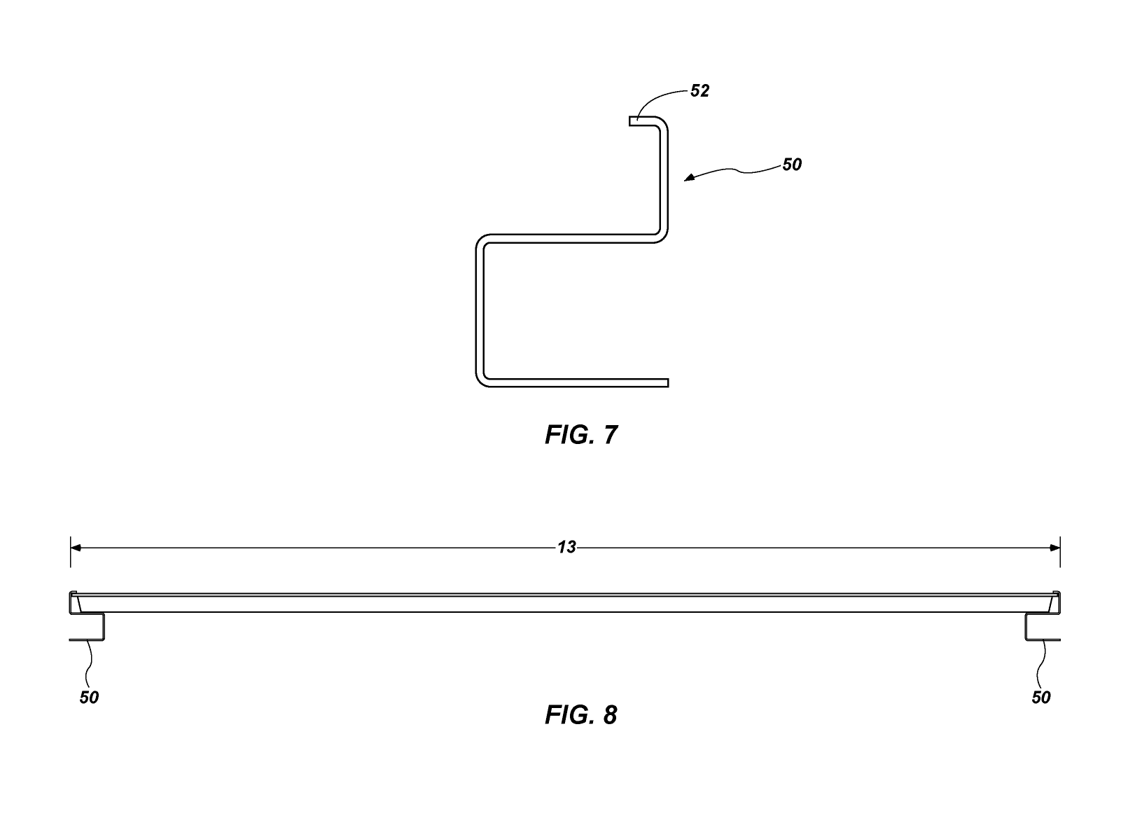

Referring to FIGS. 7 and 8, a bracket 50 may be mounted on either side of the body 12 of the PV module assembly 10. The bracket 50 may engage the body 12 on the width side 13 along the third wall 28 and fourth wall 30. Each bracket 50 may resemble an S shape body in a profile view. The bracket 50 may engage the walls 28,30 in a number of different ways. Once such engagement means may be a releasable snap fit wherein a portion of the bracket 50 snaps over a portion of the wall 28,30. A lip 52 may extend from the bracket 50 such that a force must be applied against the wall 28,30 with the bracket 50 to overcome the lip and engage the wall 28,30. The bracket 50 may be removed when the force to overcome the lip is applied in a direction opposite the force to engage the bracket 50. An alternate means to secure the bracket 50 may use screws and nuts or bolts. Other fastening means may also be used and are contemplated herein such as glues, adhesives, tapes, press fit, interference engagement, tabs, other threaded elements and the like.

Ideally, each width side 13 of the assembly 10 may include a bracket 50. Each bracket 50 is configured to secure the assembly to a mount such as a house a vehicle or other solar trackers which may sense and move with the light. The brackets 50 may include apertures or cutouts to allow for proper fastening of the bracket 50, and thus the assembly 10, to the proper location whether that be a tracker or other fixed location. The cutouts or apertures will allow for fastening mechanisms, such as screws or nuts or bolts and the like, to be passed through the cutouts or apertures to hold the assembly 10 in place on the mount.

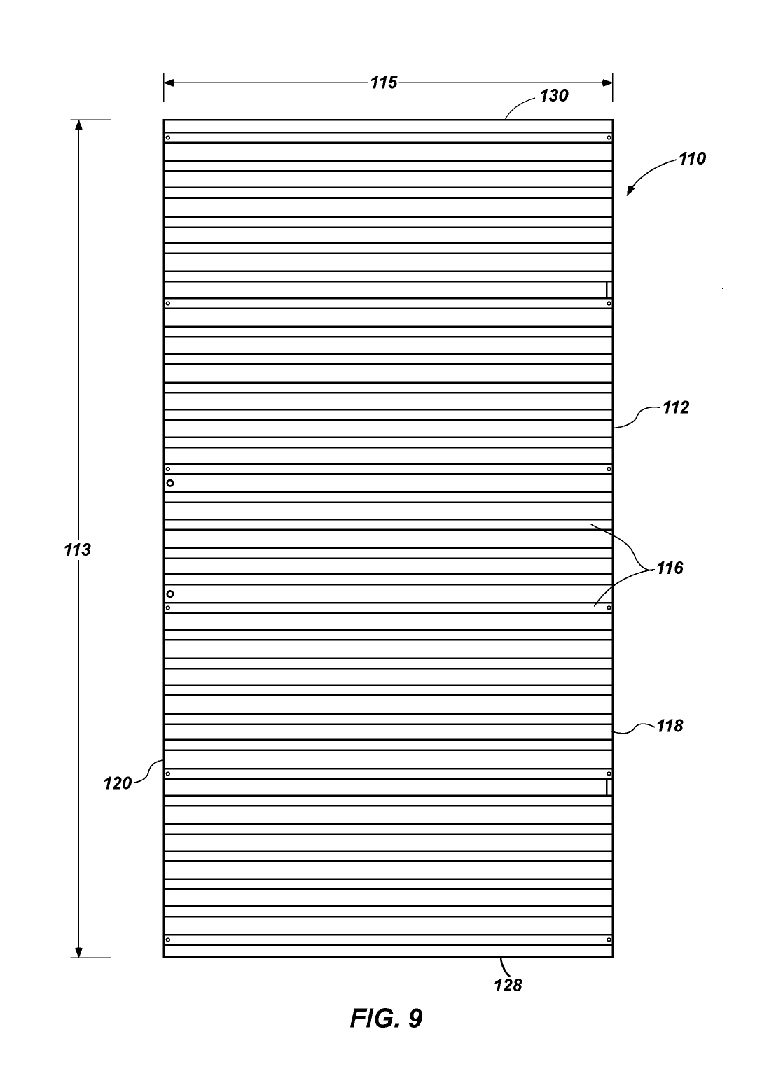

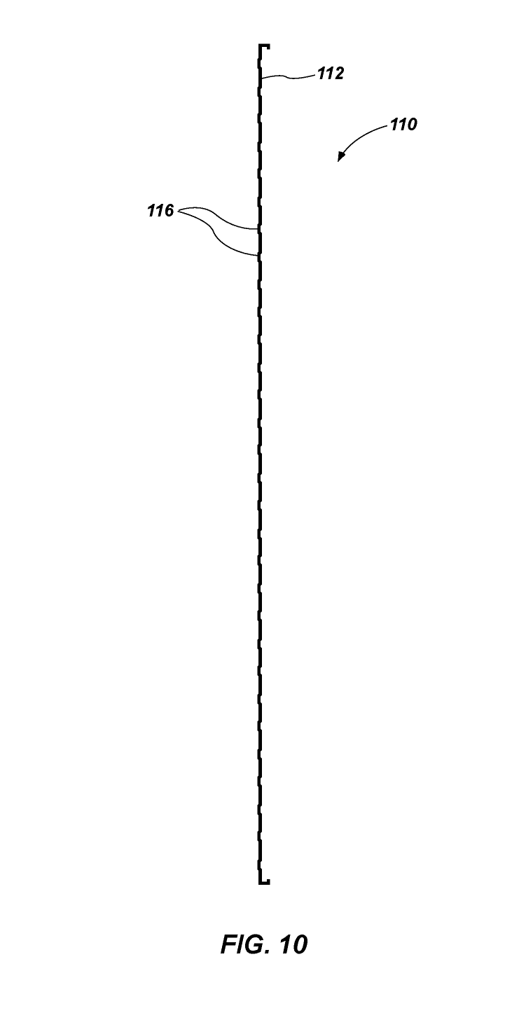

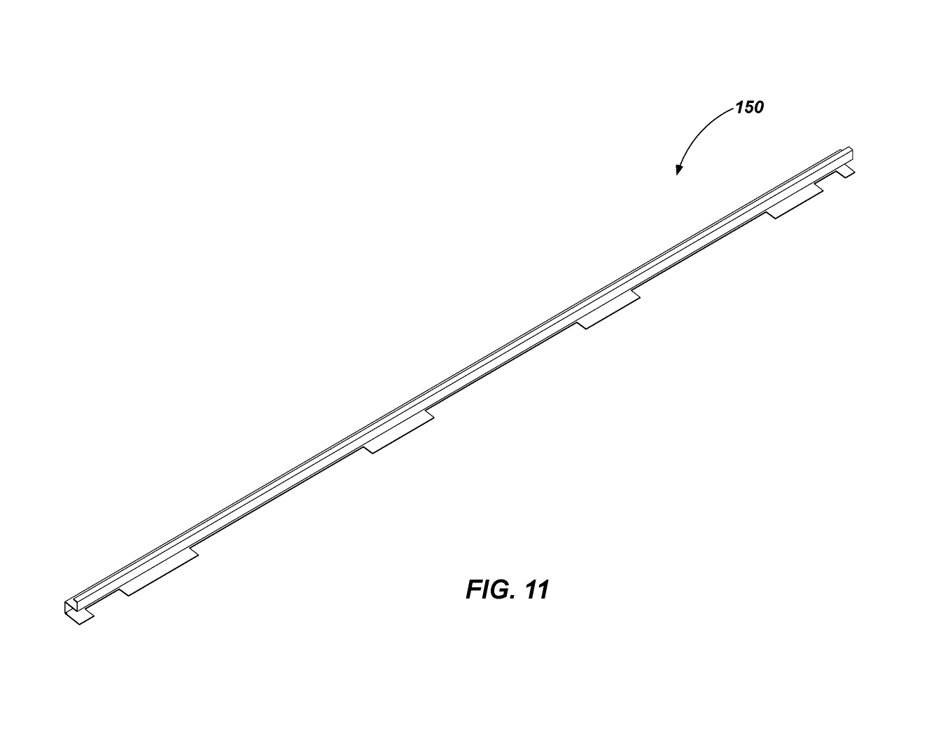

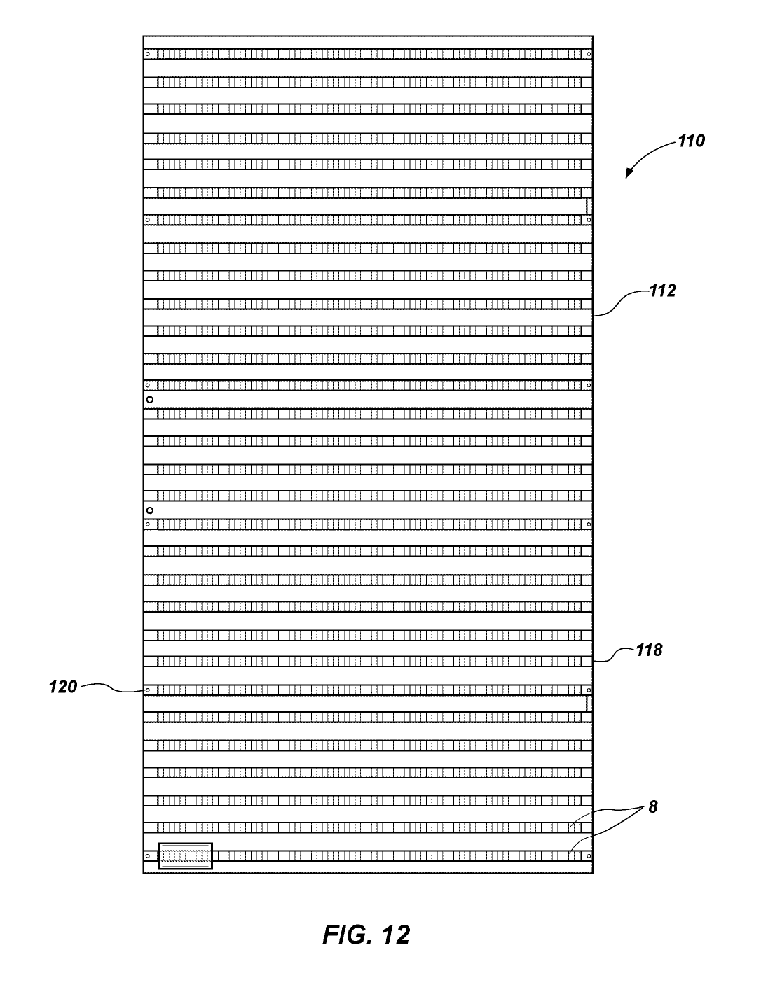

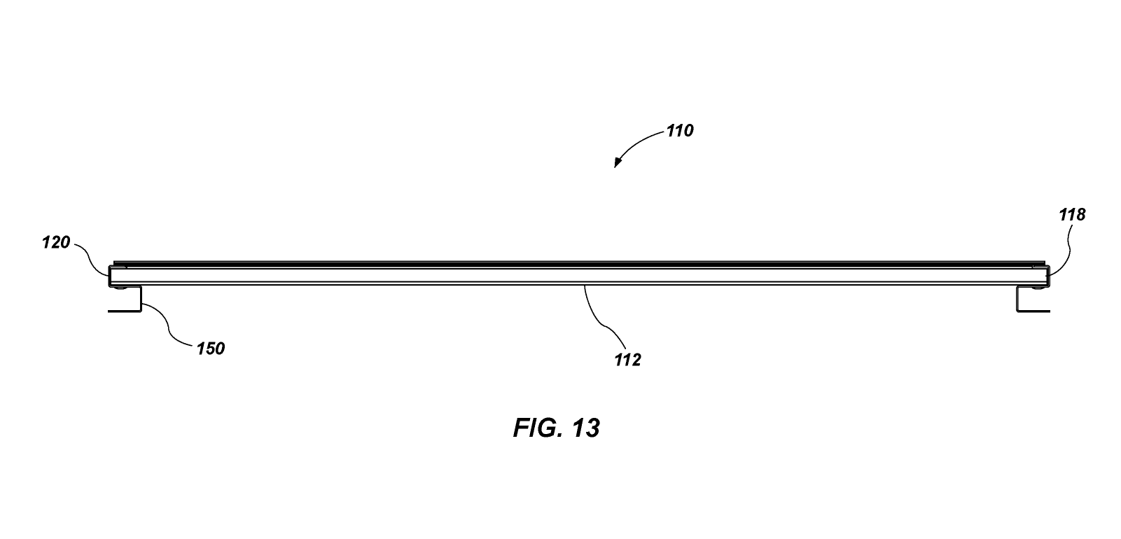

Referring to FIGS. 9 and 10, an alternate embodiment of a PV module assembly 110 is depicted. The assembly 110 includes a frame 112, or body, with a length 113 and a width 115. The frame 112 may include recesses 116 similar to the previous embodiment; however, the recesses 116 may run along the width 115 instead of the length 113 as in the previous embodiment and the recesses 116 may run parallel to each other. The recesses 116 may also run perpendicular to a first wall 118 and the second wall 120 and terminate prior to the first and second walls 118,120. Each recess 116 may extend the entire width 113 of the body 112 and may run parallel to a third wall 128 and a fourth wall 130. The number of recesses 116 may be contingent on the number of waveguides that may engage a PV cell and that may be able to be placed within the frame 112.

The current embodiment of the module 110 may include the same or similar features as the previous embodiment. The significant difference is the direction of the recesses 116 and the string of PV cells that sit within the recesses may be shorter because the direction the recesses 116 run. The number of recesses may be greater and as depicted may include thirty (30) recesses running the width 115 of the frame 112. Because of the length of the recesses a PV cell string may be much shorter than the previous embodiment and may include three to four PV cells 8, rather than ten PV cells 8, strung together as set forth previously herein.

The present embodiment of the assembly 110 may also include brackets 150 which may extend the length 115 of the frame 112 which is different from the previous embodiment that included brackets 50 that extended along the width 15 of the frame 12. The brackets 150 may include the same or similar features as the previous embodiment that allow it to engage the frame 112.

Assembling the PV module assembly 10 may be automated or may be performed manually. The steps for assembling the assembly 10 may include the following:

A PV cell may be cut into strips to allow those strips to reside within the recess 16 of the frame 12. The width of those strips may be 15 mm or similar and the length may be the standard length of the standard PV cell (156 mm). The strips of the PV cell are then soldered together to form the string of PV cells 8 as disclosed herein.

Forming the frame 12 as described herein wherein the frame 12, or pan, may include a dielectric coating that at least partially covers the surface of the frame 12 or may cover the entire surface of the frame 12. Thermally conductive tape may be applied within the recesses 16 of the frame 12 to secure the PV cells 8 to the recesses 16. The PV cells 8 may be placed within the recesses 16 and may directly engage the conductive tape securing the string of PV cells 8 to the conductive tape and thus securing the string of PV cells 8 in the recesses 16 and thus to the frame 12. Alternatively, thermally conductive adhesive may be applied to the cells that are secured to the recesses 16.

Each of the strings of PV cells 8 may be interconnected within the trough of the frame 12. Each string of PV cells 8 by be connected in serious or in parallel by using crimps and/or diodes to interconnect each PV cell to the others. With all of the PV cells interconnected an external connection may be made through cord grips to the MC4 connectors or other standard electrical connectors.

The aperture(s) 33 which include the vents may be disbursed on any of the side walls of the frame 12 and the water impermeable membrane is secured to the aperture(s) 33. The vent, or water impermeable membrane, is, ideally, secured to the aperture on the internal side of the frame, or trough side; however, it may also be secured to the outside of the aperture(s) 33 depending on means of manufacture of the aperture(s) 33 and the frame 12.

The waveguide 44 may be placed onto the lens 36 and secured to the lens 36 using an adhesive. The lens may be positioned ridged, or ribbed, side up with the flat/smooth surface laying against a surface. The waveguide 44 is secured, upside down, to the lens 36 and the waveguide is secured to a ridged surface of the lens 44. The adhesive is preferably transparent so as not to disrupt the light gathering and to optimize the amount of light passing through the lens 36 and waveguide 44.

A gel, or silicone, may be dispensed over and on top of the PV cells 8 within the recesses 16 of the frame 12. The silicone may be a two part premixed mixture of different ratios of the components which include adhesion promoters and catalysts in addition to the silicone polymer and it covers the length of the PV cells 8 in each recess 16.

A separate adhesive, gel or silicone may be dispensed on the shoulder 22 of the frame 12. The adhesive may hold the lens 36 in place on the shoulder 22 of the frame 22 to prevent movement of the lens 36 while also sealing the frame 12 preventing water ingress into the trough of the frame 12. Another layer of adhesive, gel or silicone may be dispensed along the edges of the lens 36 that lies on the shoulders 22 for added security and water ingress prevention.

Each of the silicones, gels or adhesives may be allowed to cure and dry and any excess may be trimmed from the frame 12. The PV module 10 may be tested for performance after cure. In the event of any water ingress or miss performance the assembly may be disassembled in a manner reverse of assembly and the steps for assembly repeated for reassembly for a complete PV module 10. The integrity of the sealed PV module 10 may be tested by using a vacuum pump connected to the assembly through the semi-permeable vent.

Although the foregoing disclosure provides many specifics, these should not be construed as limiting the scope of any of the ensuing claims. Other embodiments may be devised which do not depart from the scopes of the claims. Features from different embodiments may be employed in combination. The scope of each claim is, therefore, indicated and limited only by its plain language and the full scope of available legal equivalents to its elements.

1. A system for light collection, comprising:
a frame comprising at least one recess;
photovoltaic cells (PV cells) strung together linearly with an electrical connection, wherein the PV cells sit within the at least one recess;
a lens; and
a waveguide.

2. The system of claim 1, wherein the at least one recesses comprises a plurality of recesses.

3. The system of claim 2, wherein the frame further comprises a plurality of walls and shoulders extending from the walls, wherein the shoulders engage the lens.

4. The system of claim 3 further comprising at least one aperture extending through at least one of the plurality of walls.

5. The system of claim 4 comprising a water impermeable membrane configured to cover the at least one aperture extending through the at least one of the plurality of walls.

6. The system of claim 5, wherein the waveguide, on a first side, is secured to the lens and on a second side, opposite the first side, is adjacent to the PV cell.

7. The system of claim 1; wherein the PV cell is approximately 156 mm by 15 mm.

8. The system of 2, wherein the plurality of recesses extend the longitudinal length of the frame.

9. The system of claim 2, wherein the plurality of recesses extend the longitudinal width of the frame.

10. A system for light collection, comprising:
a frame comprising a body and a plurality of walls;
at least one set of photovoltaic cells (PV cells) strung together linearly with an electrical connection;
at least one waveguide configured to interact with that at least one PV cell; and
a glass, wherein the glass is smooth on one surface and ridged on a second surface.

11. The system of claim 10 comprising a plurality of recesses within the body of the frame extending longitudinally along the length of the frame.

12. The system of claim 11, wherein the at least one set of PV cells comprises a plurality of sets of PV cells, wherein the plurality of sets PV cells sit within the plurality of recesses within the frame and the PV cells extend at least partially the length of the recesses.

13. The system of claim 10, wherein the at least one waveguide comprises a plurality of waveguides, wherein one PV cell engages one waveguide.

14. The system of claim 13, wherein the waveguide comprises a first side that is secured to the second surface of the glass and a second side, opposite the first side, that is adjacent to the PV cell.

15. The system of claim 14, wherein a silicone is positioned between the PV cell and the waveguide.

16. The system of claim 10, wherein the plurality of walls comprises a shoulder configured to engage the second surface of the glass.

17. The system of claim 16, wherein in the glass is secured to the shoulder of the frame by a water impermeable adhesive.

18. A system for capturing solar energy comprising:
a frame comprising a body and a plurality of walls;
a plurality of photovoltaic cells (PV cells);
a plurality of waveguides, wherein each PV cell is configured to engage a waveguide; and
a lens, wherein the plurality of waveguides engage the lens on a first ribbed surface.

19. The system of claim 18, wherein each PV cell of the plurality of PV cells are approximately 156 mm by 15 mm and are positioned linearly, in a string, within the frame and each PV cell is connected through an electrical connection.

20. The system of claim 19, wherein ten PV cells are linearly connected with the electrical connection.

21. The system of claim 20, wherein six strings of ten PV cells each reside within the frame wherein each of the six strings of ten PV cells is connected on one end of the frame.

22. The system of claim 21, wherein the frame further comprises a plurality of recesses configured to hold the strings of PV cells.

23. The system of claim 18 wherein the lens comprises a second smooth surface, opposite the first ribbed surface wherein the second smooth surface faces away from the frame and the first ribbed surface faces toward the frame.

24. The system of claim 23, wherein the first ribbed surface of the lens is configured to engage the waveguide in such a manner that the lens focuses light energy toward the waveguide, wherein the waveguide concentrates the light energy toward the PV cell.

25. The system of claim 23, wherein the plurality of walls comprises a shoulder wherein the first ribbed surface of the lens rests on the shoulders of the plurality of walls.

26. The system of claim 18 comprising at least one hole extending through at least one of the plurality of walls wherein the aperture comprises a water impermeable vent capable of allowing water vapor to escape but preventing water ingress.
